(19) United States
(12) Patent Application Publication
(10) Pub. No.: US 2012/0182779 A1
(43) Pub. Date: Jul. 19, 2012

(54) SEMICONDUCTOR MEMORY DEVICE

(75) Inventor: Ryo FUKUDA, Kanagawa-ken (JP)

(73) Assignee: KABUSHIKI KAISHA TOSHIBA, Tokyo (JP)

(21) Appl. No.: 13/351,737

(22) Filed: Jan. 17, 2012

(30) Foreign Application Priority Data
Jan. 17, 2011 (JP) 2011-006799

(51) Int. Cl. G11C 5/06

(52) U.S. Cl. 365/63

(57) ABSTRACT

According to one embodiment, a nonvolatile memory device includes a substrate, an interconnect layer, a memory layer, a circuit layer, first and second contact interconnects. The interconnect layer is provided on the substrate and includes first and second interconnects. The memory layer is provided between the substrate and the interconnect layer and includes first and second memory cell array units. The first and second memory cell array units include a plurality of memory cells. The circuit layer is provided between the memory layer and the substrate and includes a first circuit unit. The first contact interconnect is provided between the first and second memory cell array units and electrically connects one end of the first circuit unit to the first interconnect. The second contact interconnect electrically connects a second end of the first circuit unit different from the first end to the second interconnect.

### CROSS-REFERENCE TO RELATED APPLICATIONS

This application is based upon and claims the benefit of priority from the prior Japanese Patent Application No. 2011-006799, filed on Jan. 17, 2011; the entire contents of which are incorporated herein by reference.

### FIELD

Embodiments described herein relate generally to a semiconductor device.

### BACKGROUND

A three-dimensional stacked memory has been considered in order to increase memory capacity of a semiconductor memory device. In the three-dimensional stacked memory, the configuration has been proposed, in which a memory cell is provided above the substrate and a peripheral circuit such as a sensing amplifier is provided on the substrate below the memory cell. This allows the chip areas to be reduced.

In this three-dimensional stacked memory, resistance of interconnect on a side near to the substrate may be high due to restriction of manufacturing process. This does not allow external signal inputted to the peripheral circuit to be speeded and disturbs operation of the semiconductor memory device to be speeded.

### BRIEF DESCRIPTION OF THE DRAWINGS

FIG. 1 is a schematic perspective view illustrating the configuration of a semiconductor memory device according to a first embodiment;

FIG. 2A and FIG. 2B are schematic sectional views illustrating the configuration of the semiconductor memory device according to the first embodiment;

FIG. 3A and FIG. 3B are block diagrams illustrating the configuration of the semiconductor memory device according to the first embodiment;

FIG. 4 is a block diagram illustrating the configuration of the semiconductor memory device according to the first embodiment;

FIG. 5 is a schematic perspective view illustrating the configuration of the semiconductor memory device according to the first embodiment;

FIG. 6 is a circuit diagram illustrating the configuration of the semiconductor memory device according to the first embodiment;

FIG. 7 is a schematic sectional view illustrating the configuration of the semiconductor memory device according to the first embodiment;

FIG. 8 is a block diagram illustrating the configuration of a part of the semiconductor memory device according to the first embodiment;

FIG. 9 is a block diagram illustrating the configuration of a part of the semiconductor memory device according to the first embodiment;

FIG. 10 is a schematic sectional view illustrating the configuration of a semiconductor memory device of a reference example;

FIG. 11 is a block diagram illustrating the configuration of the semiconductor memory device of the reference example;

FIG. 12 is a block diagram illustrating the configuration of a semiconductor memory device according to a second embodiment; and

FIG. 13 is a schematic perspective view illustrating the configuration of a part of a semiconductor memory device according to a third embodiment.

### DETAILED DESCRIPTION

According to one embodiment, a nonvolatile memory device includes a substrate, an interconnect layer, a memory layer, a circuit layer, a first contact interconnect and a second contact interconnect. The substrate has a major surface. The interconnect layer is provided on the major surface. The interconnect layer includes a first interconnect extending along a first direction parallel to the major surface and a second interconnect. The memory layer is provided between the substrate and the interconnect layer. The memory layer includes a first memory cell array unit and a second memory cell array unit. The first memory cell array unit includes a plurality of memory cells electrically connected to the first interconnect. The second memory cell array unit is juxtaposed to the first memory cell array unit along the first direction and includes a plurality of memory cells electrically connected to the first interconnect. The circuit layer is provided between the memory layer and the substrate and includes a first circuit unit. The first contact interconnect extends along a second direction from the substrate toward the interconnect layer between the first memory cell array unit and the second memory cell array unit and electrically connects one end of the first circuit unit to the first interconnect. The second contact interconnect extends along the second direction on a opposite side of the first memory cell array unit to the first contact interconnect and electrically connects a second end of the first circuit unit different from the first end to the second interconnect.

Various embodiments will be described hereinafter with reference to the accompanying drawings.

The drawings are schematic or conceptual, and the relationships between the thickness and width of portions, the size ratio among portions, etc., are not necessarily the same as the actual values thereof. Further, the dimensions and proportions may be illustrated differently among drawings, even for identical portions.

In the specification and drawings, the same elements as those described previously with reference to earlier figures are labeled with like reference numerals, and the detailed description is omitted as appropriate.

### First Embodiment

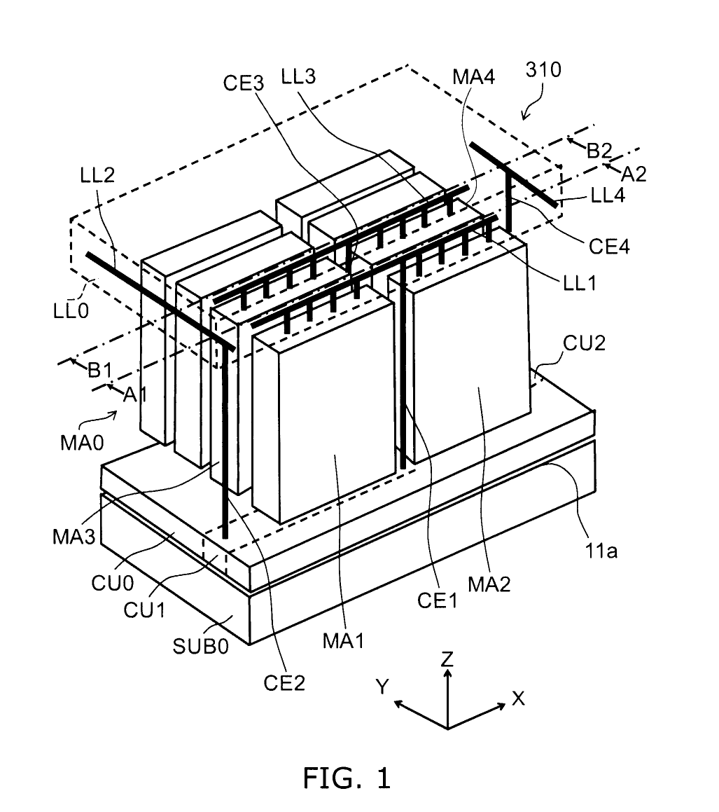

FIG. 1 is a schematic perspective view illustrating the configuration of a semiconductor memory device according to a first embodiment.

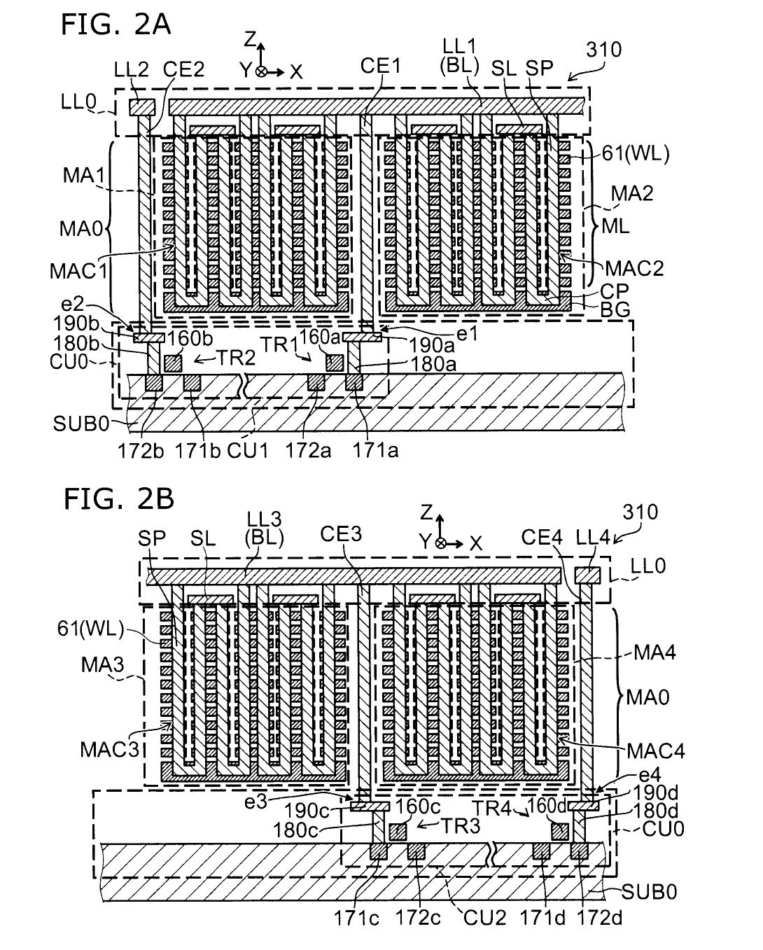

FIG. 2A and FIG. 2B are schematic sectional views illustrating the configuration of the semiconductor memory device according to the first embodiment.

In other words, FIG. 2A is an A1-A2 line sectional view, and FIG. 2B is a B1-B2 line sectional view. In FIG. 2A and FIG. 2B, conductive portions are shown and insulating portions are omitted for easy viewing.

As shown in FIG. 1 and FIG. 2A, the semiconductor memory device 310 according to the embodiment includes a substrate SUB0, an interconnect layer LL0, a memory layer MA0, a circuit layer CU0, a first contact interconnect CE1 and a second contact interconnect CE2.

The interconnect layer LL0 is provided on a major surface 11a of the substrate SUB0.

The memory layer MA0 is provided between the substrate SUB0 and the interconnect layer LL0.

The circuit layer CU0 is provided between the memory layer MA0 and the substrate SUB0.

The substrate SUB0 is illustratively based on a silicon substrate or the like. The circuit layer CU0 is provided on the major surface 11a of the silicon substrate, the memory layer MA0 is provided on the circuit layer CU0 and the interconnect layer LL0 is provided on the memory layer MA0.

Thus, the circuit layer CU0, the memory layer MA0 and the interconnect layer LL0 are stacked in this order on the substrate SUB0.

In the specification, “stack” includes direct stacking and stacking while other components are interposed as well.

Here, a direction from the substrate SUB0 toward the interconnect layer LL0 is taken as a Z-axis direction (second direction). One direction perpendicular to the Z-axis direction is taken as an X-axis direction (first direction). A direction perpendicular to the Z-axis direction and perpendicular to the X-axis direction is taken as a Y-axis direction (third direction).

The Z-axis direction is a direction perpendicular to the major surface 11a of the substrate SUB0.

The interconnect layer LL0 includes a first interconnect LL1 and a second interconnect LL2. The first interconnect LL1 extends along the X-axis direction.

In the specific example, the second interconnect LL2 extends along the Y-axis direction. For example, the second interconnect LL2 has a portion extending along the Y-axis direction.

In the specific example, the interconnect layer LL0 further includes a source line SL.

The memory layer MA0 includes a first memory cell array unit MA1 and a second memory cell array unit MA2.

The memory cell array unit MA1 includes a plurality of memory cells (for example, first memory cells MAC1 illustrated in FIG. 2A). The plurality of memory cells are electrically connected to the first interconnect LL1.

The second memory cell array unit MA2 is juxtaposed to the first memory cell array unit MA1 along the X-axis direction. The second memory cell array unit MA2 includes a plurality of memory cells (for example, second memory cells MAC2 illustrated in FIG. 2A). The plurality of memory cells are electrically connected to the first interconnect LL1.

In the specific example, a plurality of electrode films 61 are stacked along the Z-axis direction in the first memory cell array unit MA1 and the second memory cell array unit MA2. A semiconductor pillar SP is provided facing side surfaces of the plurality of electrodes 61. The memory cells are provided at portions where the semiconductor pillar SP intersects the plurality of electrode films 61. The electrode films 61 function as, for example, word lines WL. One end of the semiconductor pillar SP is connected to the first interconnect LL1. Another end of the semiconductor pillar SP is connected to the source line SL. The specific example of the configuration of the memory cells will be described later.

The circuit layer CU0 includes a first circuit unit CU1. At least a part of the first circuit unit CU1 is disposed between the first memory cell array unit MA1 and the substrate SUB0.

The first circuit unit CU1 includes, for example, a sensing amplifier circuit detecting electrical characteristics of the plurality of memory cells included in the first memory cell array unit MA1 and the plurality of memory cells included in the second memory cell array unit MA2. The first circuit unit CU1 will be described later.

The first contact interconnect CE1 extends along the Z-axis direction between the first memory cell array unit MA1 and the second memory cell array unit MA2. The first contact interconnect CE1 electrically connects one end of the first circuit unit CU1 (for example, a first end el illustrated in FIG. 2A) to the first interconnect LL1.

The second contact interconnect CE2 extends along the Z-axis direction on a side opposite to the first contact interconnect CE1 of the first memory cell array unit MA1. That is, the first memory cell array unit MA1 is disposed between the first contact interconnect CE1 and the second contact interconnect CE2. The second contact interconnect CE2 electrically connects another end (for example, a second end e2 illustrated in FIG. 2A) different from the one end (first end e1) described above of the first circuit unit CU1 to the second interconnect LL2.

The first interconnect LL1 function as, for example, a bit line BL. The second interconnect LL2 is connected to, for example, an external circuit not shown. That is, the second interconnect LL2 functions as an IOBUS connecting the first circuit unit CU1 to the external circuit.

In manufacturing the semiconductor memory device 310, for example, after the circuit layer CU0 is formed on the substrate SUB0, the memory layer MA0 is formed on the circuit layer CU0 and the interconnect layer LL0 is formed on the memory layer MA0. For example, in forming the memory layer MA0, relatively high temperature treatment is performed. Therefore, a material with high thermal stability is used for components included in the circuit layer CU0 formed before forming the memory layer MA0.

Thus, the thermal stability of a metal material included in the circuit layer CU0 is higher than the thermal stability of a metal material included in the interconnect layer LL0.

The electrical conductivity of a conductive material (metal material) included in the circuit layer CU0 is lower than the electrical conductivity of a conductive material (metal material) included in the interconnect layer LL0.

For example, the circuit layer CU0 includes tungsten. The interconnect layer LL0 includes at least one of copper and aluminum.

Thus, the electrical resistance of the metal material included in the circuit layer CU0 is higher than the electrical resistance of the metal material included in the interconnect layer LL0. At this time, in the semiconductor memory device 310, the second interconnect LL2 of the interconnect layer LL0 with low electrical resistance is used for the IOBUS. This can provide a semiconductor memory device operable at a high speed.

In the specific example, a position of the first contact interconnect CE1 along the X-axis direction is located inside the cell array region by a length of the first circuit unit CU1 along the X-axis direction.

An example of the configuration of the semiconductor memory device 310 is further described.

As shown in FIG. 1 and FIG. 2B, the semiconductor memory device 310 further includes a third contact interconnect CE3 and a fourth contact interconnect CE4.

The interconnect layer LL0 further includes a third interconnect LL3 and a fourth interconnect LL4. The third interconnect LL3 extends along the X-axis direction. The fourth interconnect LL4 extends, for example, along the Y-axis direction. For example, the first interconnect LL1 and the third interconnect LL3 are disposed between the second interconnect LL2 and the fourth interconnect LL4 along the X-axis direction.

The memory layer MA0 further includes a third memory cell array unit MA3 and a fourth memory cell array unit MA4.

At least a part of the third memory cell array unit MA3 is juxtaposed to the first memory cell array unit MA1 along the Y-axis direction. The third memory cell array unit MA3 includes a plurality of memory cells (for example, third memory cells MAC3 illustrated in FIG. 2B). The plurality of memory cells are electrically connected to the third interconnect LL3.

At least a part of the fourth memory cell array unit MA4 is juxtaposed to the third memory cell array unit MA3 along the X-axis direction. The fourth memory cell array unit MA4 is juxtaposed to the second memory cell array unit MA2 along the Y-axis direction. The fourth memory cell array unit MA4 includes a plurality of memory cells (for example, fourth memory cells MAC4 illustrated in FIG. 2B). The plurality of memory cells are electrically connected to the third interconnect LL3.

In the specific example, a plurality of electrode films 61 are stacked along the Z-axis direction in the third memory cell array unit MA3 and the fourth memory cell array unit MA4. A semiconductor pillar SP is provided facing side surfaces of the plurality of electrode films 61. The memory cells are provided at portions where the semiconductor pillar SP intersects the plurality of electrode films 61. The electrode films 61 function as, for example, word lines WL. One end of the semiconductor pillar SP is connected to the third interconnect LL3. Another end of the semiconductor pillar SP is connected to the source line SL.

The circuit layer CU0 further includes a second circuit unit CU2.

For example, at least a part of the second circuit unit CU2 is disposed between the fourth memory cell array unit MA4 and the substrate SUB0.

The second circuit unit CU2 includes, for example, a sensing amplifier circuit detecting electrical characteristics of the plurality of memory cells included in the third memory cell array unit MA3 and the plurality of memory cells included in the fourth memory cell array unit MA4.

The third contact interconnect CE3 extends along the Z-axis direction between the third memory cell array unit MA3 and the fourth memory cell array unit MA4. The third contact interconnect CE3 electrically connects one end of the second circuit unit CU2 (for example, a third end e3 illustrated in FIG. 2B) to the third interconnect LL3.

The fourth contact interconnect CE4 extends along the Z-axis direction on a side opposite to the third contact interconnect CE3 of the fourth memory cell array unit MA4. That is, the fourth memory cell array unit MA4 is disposed between the third contact interconnect CE3 and the fourth contact interconnect CE4. The fourth contact interconnect CE4 electrically connects another end (for example, a fourth end e4 illustrated in FIG. 2B) different from the one end (third end e3) described above of the second circuit unit CU2 to the fourth interconnect LL4.

The third interconnect LL3 functions as the bit line BL. The fourth interconnect LL4 extends, for example, along the Y-axis direction. The fourth interconnect LL4 functions as, for example, the IOBUS.

The fourth interconnect LL4 of the interconnect layer LL0 with low electrical resistance is used for the IOBUS. Thereby, a semiconductor memory device operable at a high speed can be provided.

As shown in FIG. 2A, the first circuit unit CU1 includes a first transistor TR1 and a second transistor TR2. The first transistor TR1 is connected to the second transistor TR2 through interconnects and circuits or the like not shown.

The first transistor TR1 includes a first diffusion layer 171a, a second diffusion layer 172a and a first gate 160a. The first diffusion layer 171a and the second diffusion layer 172a are provided, for example, in a semiconductor layer on the major surface 11a of the substrate SUB0. The first gate 160a is provided via an insulating layer on the semiconductor layer between the first diffusion layer 171a and the second diffusion layer 172a.

The second transistor TR2 includes a third diffusion layer 171b, a fourth diffusion layer 172b and a second gate 160b. The third diffusion layer 171b and the fourth diffusion layer 172b are provided, for example, in a semiconductor layer on the major surface 11a of the substrate SUB0. The second gate 160b is provided via an insulating layer on the semiconductor layer between the third diffusion layer 171b and the fourth diffusion layer 172b.

As shown in FIG. 2B, the second circuit unit CU2 includes a third transistor TR3 and a fourth transistor TR4. The third transistor TR3 is connected to the fourth transistor TR4 through interconnects and circuits or the like not shown.

The third transistor TR3 includes a fifth diffusion layer 171c, a sixth diffusion layer 172c and a third gate 160c. The fifth diffusion layer 171c and the sixth diffusion layer 172c are provided, for example, in a semiconductor layer on the major surface 11a of the substrate SUB0. The third gate 160c is provided via an insulating layer on the semiconductor layer between the fifth diffusion layer 171c and the sixth diffusion layer 172c.

The fourth transistor TR4 includes a seventh diffusion layer 171d, an eighth diffusion layer 172d and a fourth gate 160d. The seventh diffusion layer 171d and the eighth diffusion layer 172d are provided, for example, in a semiconductor layer on the major surface 11a of the substrate SUB0. The fourth gate 160d is provided via an insulating layer on the semiconductor layer between the seventh diffusion layer 171d and the eighth diffusion layer 172d.

The diffusion layers described above, for example, may be provided on the semiconductor layer provided on the insulating layer provided on the major surface 11a of the substrate SUB0. Thus, the substrate SUB0 can include a silicon layer and the first circuit unit CU1 can include a transistor having the above silicon layer as a channel.

A first to fourth array lower interconnect layers 190a to 190d are provided in layers above the first to fourth transistors TR1 to TR4.

The first diffusion layer 171a is connected to the first array lower interconnect layer 190a through a first contact 180a. The first array lower interconnect layer 190a is connected to the first contact interconnect CE1.

The fourth diffusion layer 172b is connected to the second array lower interconnect layer 190b through a second contact 180b. The second array lower interconnect layer 190b is connected to the second contact interconnect CE2.

The fifth diffusion layer 171c is connected to the third array lower interconnect layer 190c through a third contact 180c. The third array lower interconnect layer 190c is connected to the third contact interconnect CE3.

The eighth diffusion layer 172d is connected to the fourth array lower interconnect layer 190d through a fourth contact 180d. The fourth array lower interconnect layer 190d is connected to the fourth contact interconnect CE4.

The first to fourth gates 160a to 160d are based on, for example, polysilicon. The first to fourth array lower interconnect layers 190a to 190d are based on, for example, tungsten or the like.

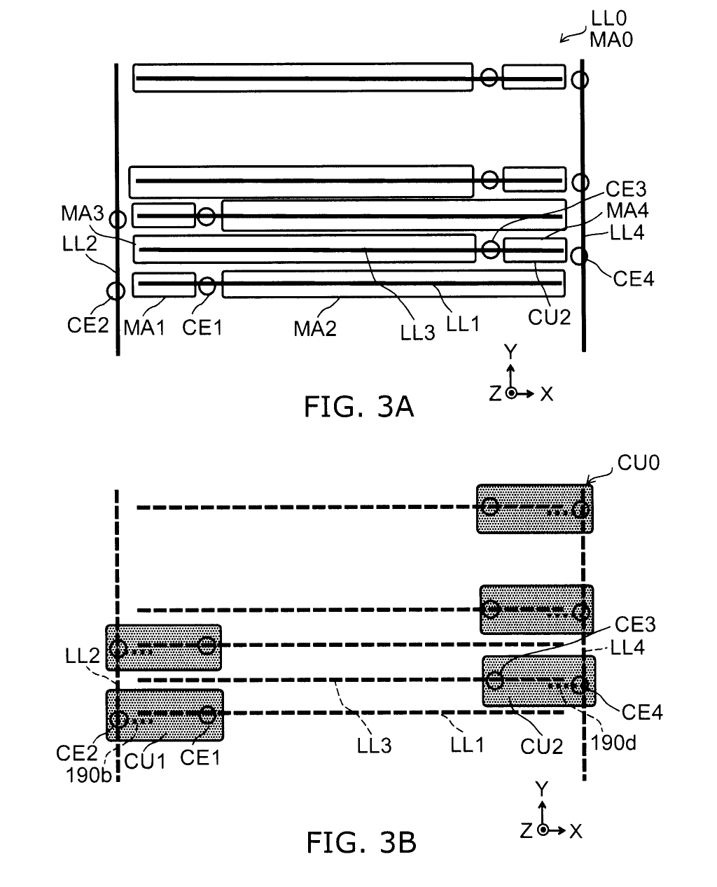

FIG. 3A and FIG. 3B are block diagrams illustrating the configuration of the semiconductor memory device according to the first embodiment.

In other words, FIG. 3A illustrates the configuration of the interconnect layer LL0 and the memory layer MA0, and FIG. 3B illustrates the configuration of the circuit layer CU0.

As shown in FIG. 3A, the second interconnect LL2 is provided on one end of the first to fourth memory cell array units MA1 to MA4 along the X-axis direction, and the fourth interconnect LL4 is provided on another end. The first interconnect LL1 and the third interconnect LL3 are provided between the second interconnect LL2 and the fourth interconnect LL4.

The first contact interconnect CE1 is provided in the middle of the first interconnect LL1. The third contact interconnect CE3 is provided in the middle of the third interconnect LL3.

In the specific example, a position of the first contact interconnect CE1 along the X-axis direction and a position of the third contact interconnect CE3 along the X-axis direction are disposed between a position of the second contact interconnect CE2 along the X-axis direction and a position of the fourth contact interconnect CE4 along the X-axis direction.

A length of the first memory cell array unit MA1 along the X-axis direction is longer than a length of the second memory cell array unit MA2 along the X-axis direction.

A length of the third memory cell array unit MA3 along the X-axis direction is longer than a length of the fourth memory cell array unit MA4 along the X-axis direction.

Such interconnects are arranged along the Y-axis direction in a plurality. The memory cell array unit connected to each of the interconnects are arranged along the Y-axis direction in a plurality. The number of the interconnects and the number of the memory cell arrays are optional.

As shown in FIG. 3B, the first circuit unit CU1 is connected to the first interconnect LL1 through the first contact interconnect CE1, and connected to the second interconnect LL2 through the second contact interconnect CE2. The second circuit unit CU2 is connected to the third interconnect LL3 through the third contact interconnect CE3, and connected to the fourth interconnect LL4 through the fourth contact interconnect CE4.

The first circuit unit CU1 is provided on one end along the X-axis direction. The second circuit unit CU2 is provided on another end along the X-axis direction. Thus, a plurality of circuit units are provided alternatively on two ends of the memory cell array units along the X-axis direction. Thus, a pitch of the plurality of circuit units along the Y-axis direction is two times of a pitch of the BL lines (for example, the first interconnect LL1 and the third interconnect LL3 or the like) along the Y-axis direction. Thus, a width of the circuit unit along the Y-axis direction can be made large and a design margin is increased. Thereby, performance of the circuit unit can be improved. In other words, a width of the first circuit unit CU1 along the Y-axis direction can be set not less than a distance between the center of the first interconnect LL1 in the Y-axis direction and the center of the third interconnect LL3 in the Y-axis direction.

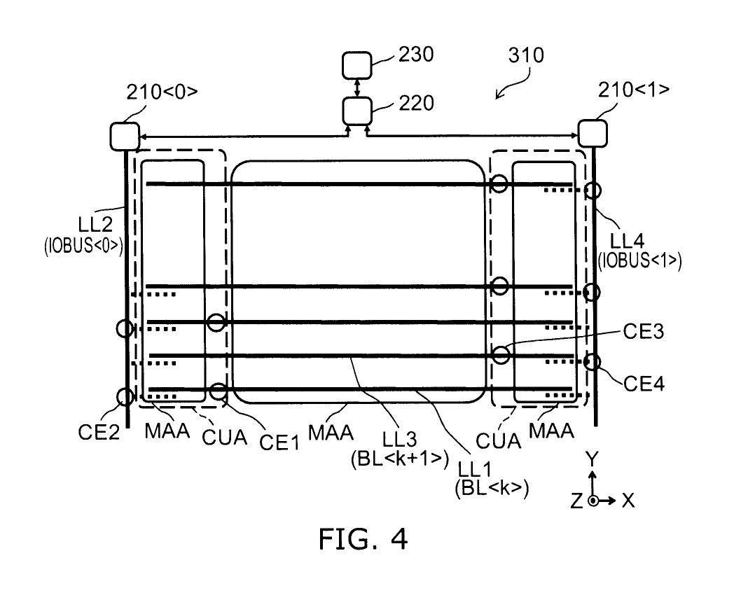

FIG. 4 is a block diagram illustrating the configuration of the semiconductor memory device according to the first embodiment.

Here, the first memory cell array unit MA1 to the fourth memory cell array unit MA4 are assumed to be included in a memory cell array unit MAA. The first circuit unit CU1 and the second circuit unit CU2 are assumed to be included in a circuit unit CUA.

As shown in FIG. 4, the second interconnect LL2 is provided on one end of the memory cell array unit MAA along the X-axis direction, and the fourth interconnect LL4 is provided on another end. The first interconnect LL1 and the third interconnect LL3 extend along the X-axis direction above the memory cell array unit MAA.

The first interconnect LL1 is a bit line BL<k>, and the third interconnect LL3 is a bit line BL<k+1> (k is a positive integer). The bit line BL<k+1> is adjacent to the bit line BL<k>.

The second interconnect LL2 functions as an IOBUS<0>. The fourth interconnect LL4 functions as an IOBUS<1>. The IOBUS<0> is connected to a circuit 210<0>. The circuit 210<0> is connected to an IO buffer 220. The IOBUS<1> is connected to a circuit 210<1>. The circuit 210<1> is connected to the IO buffer 220. The IO buffer 220 is connected to a pad 230. Data transfer to and from the external circuit is performed through the IOBUS<0> and the IOBUS<1>.

The IOBUS<0> and the IOBUS<1> are based on interconnects included in the upper layer of the interconnect layer LL0. Therefore, the high-speed operation becomes possible in a path from the sensing amplifier circuit of the circuit unit CUA to the external circuit via the IOBUS<0> and the IOBUS<1>.

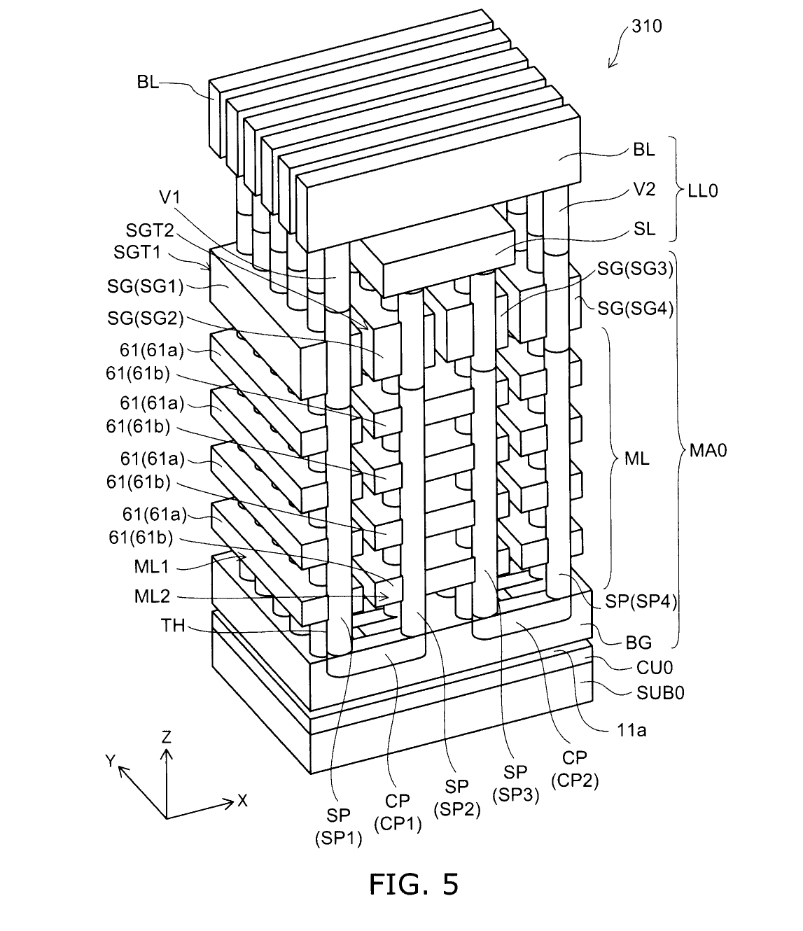

FIG. 5 is a schematic perspective view illustrating the configuration of the semiconductor device according to the first embodiment. FIG. 5 shows a self-array configuration of the semiconductor device according to the embodiment. This semiconductor memory device may be called BiCS. The BiCS is one of three-dimensional stacked memory devices. However, the embodiment is not limited to the BiCS. BiCS is not limited by the description of the specification.

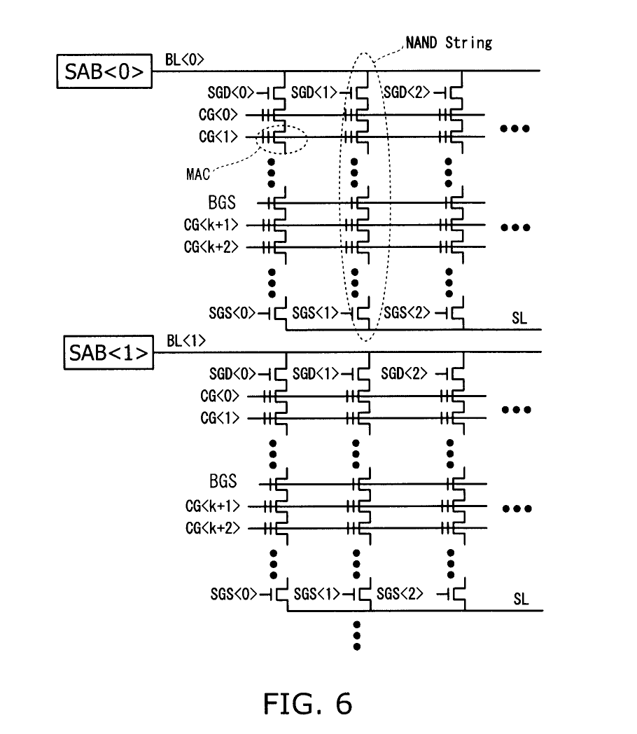

FIG. 6 is a circuit diagram illustrating the configuration of the semiconductor memory device according to the first embodiment.

In other words, FIG. 6 shows the circuit diagram of the self-array portion of the BiCS.

In FIG. 6, the BL<k> (K=0, 1, 2, - - - ) shows the bit line BL. A drain of a selection gate transistor SGDT is connected to the bit line BL. A string selection signal SGD<i> (i=o, 1, 2, - - - ) is inputted to a gate of the selection gate transistor SGDT.

A plurality of memory cell transistors (memory cells MAC) are connected in series on a source side of the selection gate transistor SGDT. The memory cell transistor functions as a memory by storing electrons in a floating film inside the memory cell transistor to change a threshold value. A high-density nonvolatile memory device is realized by stacking three-dimensionally the plurality of memory cell transistors.

Each of gate control signals CG<j> (j=0, 1, 2, - - - ) being different depending on layers is inputted to each of the gates of the stacked plurality of memory cell transistors.

The lowest end of a through hole TH illustrated in FIG. 5 is a back gate transistor, and the through hole is folded back at the end. The lowest end is connected to the memory cell transistors in series. A back gate control signal BGS is inputted to the gate of the back gate transistor.

A drain terminal of a selection gate transistor SGST is connected to a source terminal of the memory cell transistor in the uppermost layer. One NAND string is formed of the selection gate transistor SGDT, the plurality of memory cell transistors, the back gate transistor, the plurality of memory cell transistors and the selection gate transistor SGST.

As shown in FIG. 5, the bit lines BL extend, for example, along the X-axis direction. The plurality of bit lines BL are arranged along the Y-axis direction. Each of the plurality of bit lines BL is connected to each of a plurality of sensing amplifier blocks SAB.

The gate control signal CG<j> of the memory cell in one layer is shared by a plurality of NAND strings because of extraction.

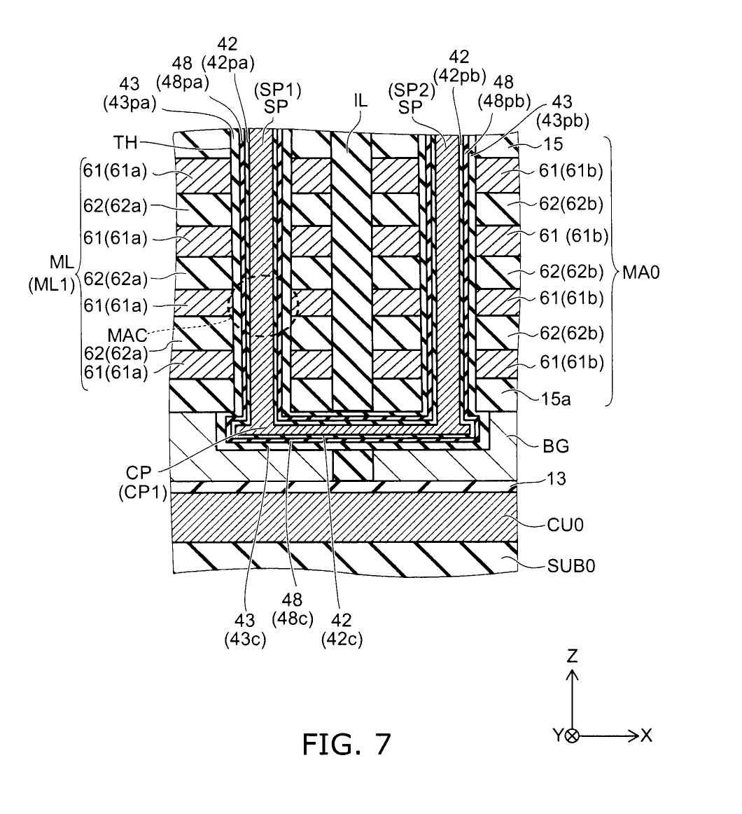

FIG. 7 is a schematic sectional view illustrating the configuration of the semiconductor memory device according to the first embodiment. FIG. 5 and FIG. 7 illustrate the configuration of a part of the memory cell array units MAA (for example, first to fourth memory cell array units MA1 to MA4 or the like).

In FIG. 5, conductive portions are shown and insulating portions are omitted for easy viewing. In FIG. 5 and FIG. 7, the case of the number of the electrode films 61 being 4 is shown for easy viewing. Hereinafter, an example of components included in the memory layer MA0 will be described with regard to the first memory cell array unit MA1.

As shown in FIG. 5 and FIG. 7, the first memory cell array unit MA1 includes a first stacked structure ML1 and a second stacked structure ML2. The first stacked structure ML1 and the second stacked structure ML2 are provided on the circuit layer CU0 on the major surface 11a of the substrate SUB0.

The first stacked structure ML1 has a plurality of first electrode films 61a and a plurality of first inter-electrode insulating films 62a alternately stacked in the Z-axis direction.

The second stacked structure ML2 juxtaposed with the first stacked structure ML1 in a direction perpendicular to the Z-axis direction (in the specific example, the X-axis direction). The second stacked structure ML2 has a plurality of second electrode films 61b and a plurality of inter-electrode insulating films 62b alternately stacked in the Z-axis direction.

In the specific example, the first electrode films 61a and the second electrode films 61b extend along the Y-axis direction.

Each of the plurality of first electrode films 61a and each of the plurality of second electrode films 61b are in one layer. For example, a distance between the substrate SUB0 and each of the plurality of first electrode films 61a is the same as a distance between the substrate SUB0 and each of the plurality of second electrode films 61b. A distance between the substrate SUB0 and each of the plurality of first inter-electrode insulating films 62a is the same as a distance between the substrate SUB0 and each of the plurality of second inter-electrode insulating films 62b.

The first memory cell array unit MA1 further includes a first semiconductor pillar SP1, a second semiconductor pillar SP2, a first memory unit and a second memory unit.

The second semiconductor pillar SP2 juxtaposed with the first semiconductor pillar SP1 along the X-axis direction.

The first semiconductor pillar SP1 faces side surfaces of the first electrode films 61a. The second semiconductor pillar SP2 faces side surfaces of the second electrode films 61b.

In the specific example, the first semiconductor pillar SP1 pierces the first stacked structure ML1 along the Z-axis direction. The second semiconductor pillar SP2 pierces the second stacked structure ML2 along the Z-axis direction.

The first memory unit is provided between the plurality of first electrode films 61a and the first semiconductor pillar SP1. The second memory unit is provided between the plurality of second electrode films 61b and the second semiconductor pillar SP2.

The first memory unit includes, for example, a first pillar unit memory layer 48pa provided between the plurality of first electrode films 61a and the first semiconductor pillar SP1, a first pillar unit outer insulating films 43pa provided between the first pillar unit memory layer 48pa and the plurality of first electrode films 61a, and a first pillar unit inner insulating film 42pa provided between the first pillar unit memory layer 48pa and the first semiconductor pillar SP1.

The second memory unit includes, for example, a second pillar unit memory layer 48pb provided between the plurality of second electrode films 61b and the second semiconductor pillar SP2, a second pillar unit outer insulating films 43pb provided between the second pillar unit memory layer 48pb and the plurality of second electrode films 61b, and a second pillar unit inner insulating film 42pb provided between the second pillar unit memory layer 48pb and the second semiconductor pillar SP2.

The first memory cell array unit MA1 further includes a semiconductor connection unit CP (first semiconductor connection unit CP1) connecting one end of the first semiconductor pillar SP1 to one end of the second semiconductor pillar SP2, a connection unit conductive layer BG (back gate) facing the semiconductor connection unit CP, and a connection unit insulating film provided between the semiconductor connection unit CP and the connection unit conductive layer BG. The semiconductor connection unit CP is, for example, based on materials serving as the first semiconductor pillar SP1 and the second semiconductor pillar SP2.

The connection unit insulating film includes, for example, a connection unit memory layer 48c provided between the semiconductor connection unit CP and the connection unit conductive layer BG, a connection unit outer insulating film 43c provided between the connection unit memory layer 48c and the connection unit conductive layer BG, and a connection unit inner insulating film 42c provided between the connection unit memory layer 48c and the semiconductor connection unit CP.

The memory layer 48 includes the first pillar unit memory layer 48pa, the second pillar unit memory layer 48pb, and the connection unit memory layer 48c. The memory layer 48 stores or discharges a charge, for example, by electric field applied between the semiconductor pillar SP and the electrode films 61, and functions as a portion storing information. The memory layer 48 may be a monolayer film and may be a stacked film.

A prescribed electrical signal is applied to the electrode films 61. The electrode films 61 function as the word line WL and the bit line BL.

The connection unit conductive layer BG is, for example, set to prescribed potential. This controls, for example, the electrical connection by the semiconductor connection unit CP between the first semiconductor pillar SP1 and the second semiconductor pillar SP2.

The electrode films 61 and the connection unit conductive layer BG can be based on optional conductive materials, for example, amorphous silicon (noncrystalline silicon) having conductivity given by introduced impurity, or polysilicon (polycrystalline silicon) having conductivity given by introduced impurity, or the like, and a metal or alloy or the like as well.

For example, the through hole TH is formed in the stacked structure ML. A film serving as the outer insulating film 43, a film serving as the memory layer 48, and a film serving as the inner insulating film 42 are formed on an inner wall of the through hole TH. After that, a semiconductor serving as the semiconductor pillar SP is buried in a residual space. Thus, the configuration described above is formed.

The first stacked structure ML1 and the second stacked structure ML2 are divided by an insulating layer IL.

In the first memory cell array unit MA1, the memory cell transistors having the memory layer 48 are formed at portions where the electrode films 61 intersect the semiconductor pillar SP. The memory cell transistors are arranged in a three-dimensional matrix configuration. Each memory cell transistor functions as the memory cell MAC (first memory cell MAC1 or the like) storing the data by making a charge store in the memory layer 48. In other words, the first and second semiconductor pillars SP1 and SP2 connected by the first semiconductor connection unit CP1 are paired to be one U-shaped NAND string.

As illustrated in FIG. 7, an interlayer insulating film 13 is provided between the circuit layer CU0 and the memory layer MA0. Interlayer insulating films 15a are provided between the connection unit conductive layer BG and the electrode films 61. An interlayer insulating film 15 is provided on the uppermost electrode film 61.

As shown in FIG. 5, the memory cell array unit MA1 further includes a first selection gate electrode SG1 stacked with the first stacked structure ML1 along the Z-axis direction and pierced by the first semiconductor pillar SP1, and a second selection gate electrode SG2 stacked with the second stacked structure ML2 along the Z-axis direction and pierced by the second semiconductor pillar SP2. A selection gate insulating film (not shown) is provided between these selection gate electrodes SG (first selection gate electrode SG1 and second selection gate electrode SG2 or the like) and the semiconductor pillar SP.

The first selection gate electrode SG1 and the second selection gate electrode SG2 extend along the Y-axis direction.

A first selection gate transistor SGT1 is formed at a portion where the first selection gate electrode SG1 intersect the first semiconductor pillar SP1, and a second selection gate transistor SGT2 is formed at a portion where the second selection gate electrode SG2 intersect the second semiconductor pillar SP2.

As illustrated in FIG. 5, the bit line BL and the source line SL are provided in the interconnect layer LL0. The bit line BL is connected to another end of the first semiconductor pillar SP1 on an opposite side to the first semiconductor connection unit CP1. The source line SL is connected to another end of the second semiconductor pillar SP2 on an opposite side to the first semiconductor connection unit CP1. In the specific example, the bit line BL extends along the X-axis direction and the source line SL extends along the Y-axis direction.

The memory strings having this configuration are repeatedly provided along the X-axis direction and the Y-axis direction.

For example, a third semiconductor pillar SP3 and a fourth semiconductor pillar SP4 are provided to be juxtaposed with the second semiconductor pillar SP2 along the X-axis direction. The second semiconductor pillar SP2 is provided between the third semiconductor pillar SP3 and the first semiconductor pillar SP1. The third semiconductor pillar SP3 is provided between the fourth semiconductor pillar SP4 and the second semiconductor pillar SP2. The third semiconductor pillar SP3 and the fourth semiconductor pillar Sp4 are connected by the second semiconductor connection unit CP2. The third semiconductor pillar SP3 pierces through a third selection gate electrode SG3. The fourth semiconductor pillar SP4 pierces through a fourth selection gate electrode SG4.

The bit line BL is further connected to another end of the fourth semiconductor pillar SP4 on an opposite side to the second semiconductor connection unit CP2. The source line SL is further connected to another end of the third semiconductor pillar SP3 on an opposite side to the second semiconductor connection unit CP2. The first semiconductor pillar SP1 is connected to the bit line BL through a via V1, and the fourth semiconductor pillar SP4 is connected to the bit line BL through a via V2.

The configuration described above allows intended data to be programmed, deleted and read out to and from an optional memory cell MAC (first to fourth memory cells MAC1 to MAC4 or the like) of an optional semiconductor pillar SP.

Thus, in the semiconductor memory device 310 according to the embodiment, the plurality of memory cells (for example, first memory cell MAC1) included in the first memory cell array unit MA1 are stacked along the Z-axis direction. The plurality of memory cells (for example, second memory cell MAC2) included in the second memory cell array unit MA2 are stacked along the Z-axis direction.

The first memory cell array unit MA1 may include the stacked structure ML including the plurality of electrode films 61 stacked along the Z-axis direction and the inter-electrode insulating films 62 provided between the plurality of electrode films 61, the semiconductor layer (for example, semiconductor pillar SP) facing the side surfaces of the plurality of electrode films 61 along the Z-axis direction, the memory layer (for example, memory layer 48) provided between the semiconductor layer and the plurality of electrode films 61, the first insulating film (for example, inner insulating film 42) provided between the memory layer and the semiconductor layer, and the second insulating film (for example, outer insulating film 43) provided between the memory layer and the plurality of electrode films 61.

The semiconductor layer described above is electrically connected to the first interconnect LL1. Each of the plurality of memory cells included in the first memory cell array MA1 is provided on a portion where each of the plurality of electrode films 61 faces the semiconductor layer described above.

For example, the first memory cell array unit MA1 includes the first stacked structure ML1 including the plurality of first electrode films 61a stacked along the Z-axis direction and the first inter-electrode insulating films 62a provided between the plurality of first electrode films 61a, the first semiconductor pillar SP1 piercing the first stacked structure ML1 along the Z-axis direction, the first memory layer (first pillar unit memory layer 48pa) provided between the first semiconductor pillar SP1 and the plurality of first electrode films 61a, the first inner insulating film (first pillar unit inner insulating film 42pa) provided between the first memory layer and the first semiconductor pillar SP1, and the first outer insulating film (first pillar unit outer insulating film 43pa) provided between the first memory layer and the plurality of first electrode films 61a.

The first semiconductor pillar SP1 is electrically connected to the first interconnect LL1. Each of the plurality of memory cells included in the first memory cell array unit MA1 is provided at a portion where each of the plurality of first electrode films 61a and the first semiconductor pillar SP1.

Furthermore, the first memory cell array unit MA1 includes the second stacked structure ML2 juxtaposed to the first stacked structure ML1 along the X-axis direction and including the plurality of second electrode films 61b stacked along the Z-axis direction and the second inter-electrode insulating films 62b provided between the plurality of second electrode films 61b, the second semiconductor pillar SP2 piercing the second stacked structure ML2 along the Z-axis direction, the second memory layer (second pillar unit memory layer 48pb) provided between the second semiconductor pillar SP2 and the plurality of second electrode films 61b, the second inner insulating film (second pillar unit inner insulating film 42pb) provided between the second memory layer and the second semiconductor pillar SP2, the second outer insulating film (second pillar unit outer insulating film 43pb) provided between the second memory layer and the plurality of second electrode films 61b, and the semiconductor connection unit CP electrically connecting one end of the first semiconductor pillar SP1 to one end of the second semiconductor pillar Sp2.

Each of the plurality of memory cells included in the first memory cell array unit MA1 is further provided at a portion where each of the plurality of second electrode films 61b and the second semiconductor pillar SP2.

The interconnect LL0 further includes a second semiconductor pillar interconnect (source line SL) connected to another end opposite to one end of the second semiconductor pillar SP2.

A distance between at least a part of the second interconnect LL2 and the substrate SUB0 is equal to at least one of a distance between the first interconnect LL1 and the substrate SUB0 and a distance between the second semiconductor pillar interconnect (source line SL) and the substrate SUB0.

As shown in FIG. 2A and FIG. 2B, the second interconnect LL2 and the forth interconnect LL4 are in the same layer as the first interconnect LL1 and the third interconnect LL3, however the embodiment is not limited thereto. For example, conductive layers on an upper side or lower side of the first interconnect LL1 and the third interconnect LL3 may be used for the second interconnect LL2 and the fourth interconnect LL4. For example, conductive layers used for the first interconnect LL1 and the third interconnect LL3 and conductive layers used for the source line SL may be used for the second interconnect LL2 and the fourth interconnect LL4.

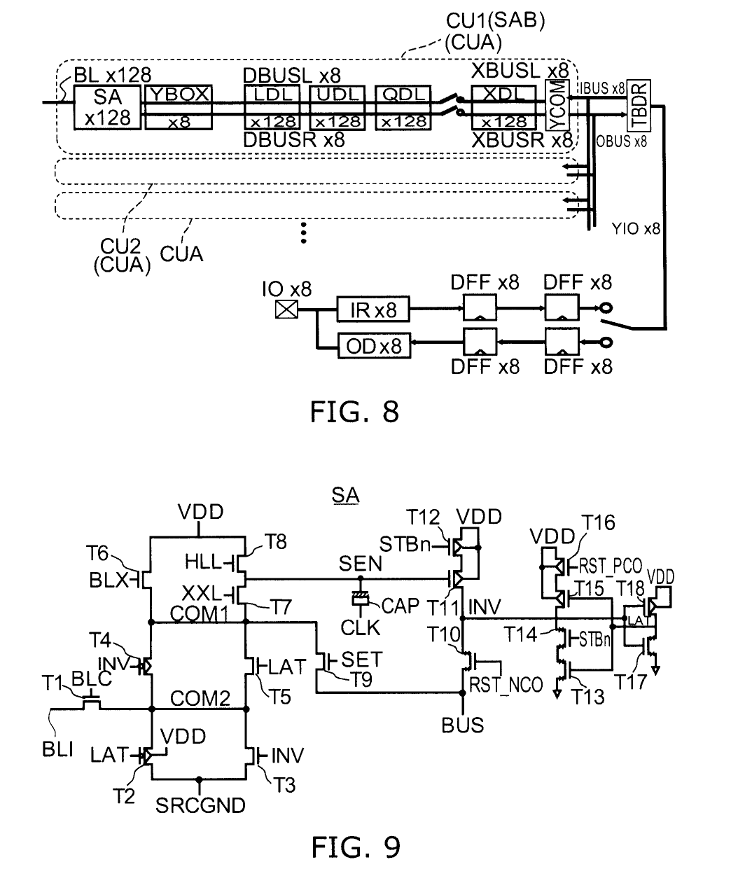

FIG. 8 is a block diagram illustrating the configuration of a part of the semiconductor memory device according to the first embodiment.

In other words, FIG. 8 shows one example of the configuration of the circuit unit CUA (for example, first circuit unit CU1 and second circuit unit CU2 or the like).

As shown in FIG. 8, the circuit unit CUA includes the sensing amplifier block SAB. The sensing amplifier block SAB includes a sensing amplifier circuit SA. The sensing amplifier block SAB further includes a latch logic circuit YBOX, an L data latch circuit LDL, a U data latch circuit UDL, a Q data latch circuit QDL, an X data latch circuit XDL, and a select switch circuit YCOM.

For example, each of 128 bit lines BL is connected to the sensing amplifier circuit SA. The sensing amplifier circuit SA is connected to the select switch circuit YCOM via the latch logic circuit YBOX, the L data latch circuit LDL, the U data latch circuit UDL, the Q data latch circuit QDL and the X data latch circuit XDL. These connections are performed by an interconnect DBUSL, an interconnect DBUSR, an interconnect XBUSL and an interconnect XBUSR.

The select switch circuit YCOM is connected to an input bus IBUS and an output bus OBUS.

The first interconnect LL1 and the third interconnect LL3 correspond to the bit lines BL. In other word, the first interconnect LL1 and the third interconnect LL3 are connected to the sensing amplifier circuit SA. The second interconnect LL2 and the fourth interconnect LL4 are used as the input bus IBUS and the output bus OBUS.

The input bus IBUS and the output bus OBUS are connected to an input/output control unit TBDR. The input/output control unit TBDR is connected to a data flip-flop circuit DFF via an input/output interconnect YIO. The data flip-flop circuit DFF is connected to an input receiver IR and an output driver OD. The input receiver IR and the output driver OD are connected to an input/output terminal IO.

The above is one example, and the circuit unit CUA (for example, first circuit unit CU1 and second circuit unit CU2 or the like) is optionally configured.

FIG. 9 is a block diagram illustrating the configuration of a part of the semiconductor memory device according to the first embodiment.

In other words, FIG. 9 shows one example of the configuration of the sensing amplifier circuit SA.

As shown in FIG. 9, the sensing amplifier circuit SA includes first to eighteenth MOS transistors T1 to T18 and a capacitor CAP.

A bit line signal BLI is inputted to one end of the first MOS transistor T1. A BL cramp signal BLC is inputted to a gate of the first MOS transistor T1. One ends of the second to fifth MOS transistors T2 to T5 are connected to another end of the first MOS transistor T1. Potential at the another end of the first MOS transistor T1 includes a signal COM2.

A signal LAT is inputted to a gate of the second MOS transistor T2. Another end of the second MOS transistor T2 and another end of the third MOS transistor T3 are set to potential SRCGND.

A signal INV is inputted to a gate of the third MOS transistor T3.

The signal INV is inputted to a gate of the fourth MOS transistor T4. Another end of the fourth MOS transistor T4 is connected to one end of the sixth MOS transistor T6.

A signal BLX is inputted to a gate of the sixth MOS transistor T6. Another end of the sixth MOS transistor T6 is set to potential VDD.

The signal LAT is inputted to a gate of the fifth MOS transistor T5. Another end of the fifth MOS transistor T5 is connected to one end of the seventh MOS transistor T7.

A signal XXL is inputted to a gate of the seventh MOS transistor T7. Another end of the seventh MOS transistor T7 is connected to one end of the eighth MOS transistor T8.

A signal HHL is inputted to a gate of the eighth MOS transistor T8. Another end of the eighth MOS transistor T8 is set to the potential VDD.

The another end of the fourth MOS transistor T4, the another end of the fifth MOS transistor T5, the one end of the sixth MOS transistor T6 and the one end of the seventh MOS transistor T7 are mutually connected. Potential at this connection point includes a signal COM1. This connection point is connected to one end of the ninth MOS transistor T9.

A signal SET is inputted to a gate of the ninth MOS transistor T9. Another end of the ninth MOS transistor T9 is connected to one end of the tenth MOS transistor T10.

A signal RST_NCO is inputted to a gate of the tenth MOS transistor T10. Another end of the tenth MOS transistor is connected to one end of the eleventh MOS transistor T11.

A gate of the eleventh MOS transistor T11 is connected to the another end of the seventh MOS transistor T7 and the one end of the eighth MOS transistor T8. One end of the capacitor CAP is connected to a connection point of the another end of the seventh MOS transistor T7 and the one end of the eighth MOS transistor T8, and the gate of the eleventh MOS transistor T11. A signal CLK is inputted to another end of the capacitor CAP.

Another end of the eleventh MOS transistor T11 is connected to one end of the twelfth MOS transistor T12. A signal STBn is inputted to a gate of the twelfth MOS transistor T12. Bases of the eleventh MOS transistor T11 and the twelfth MOS transistor T12 are set to the potential VDD.

A connection point of the another end of the tenth MOS transistor T10 and the one end of the eleventh MOS transistor T11 is connected to one end of the fourteenth MOS transistor T14 and one end of the fifteenth MOS transistor T15.

The signal STBn is inputted to a gate of the fourteenth MOS transistor T14. Another end of the fourteenth MOS transistor T14 is connected to one end of the thirteenth MOS transistor T13.

Another end of the thirteenth MOS transistor T13 is set to low potential.

Another end of the fifteenth MOS transistor T15 is connected to one end of the sixteenth MOS transistor T16.

A signal RST_PCO is inputted to a gate of the sixteenth MOS transistor T16. Bases of the fifteenth MOS transistor T15 and the sixteenth MOS transistor T16 are set to the potential VDD.

A connection point of the another end of the tenth MOS transistor T10 and the one end of the eleventh MOS transistor T11 is connected to a gate of the seventeenth MOS transistor T17 and a gate of the eighteenth MOS transistor T18.

One end of the seventeenth MOS transistor T17 is connected to one end of the eighteenth MOS transistor T18. Another end of the seventeenth MOS transistor T17 is set to low potential.

Another end and a base of the eighteenth MOS transistor T18 is set to the potential VDD.

A connection point of the one end of the seventeenth MOS transistor T17 and the one end of the eighteenth MOS transistor T18 is connected to a gate of the thirteenth MOS transistor T13 and a gate of the fifteenth MOS transistor T15. The signal LAT is inputted to the one end of the seventeenth MOS transistor T17, the one end of the eighteenth MOS transistor T18, the gate of the thirteenth MOS transistor T13 and the gate of the fifteenth MOS transistor T15.

The another end of the ninth MOS transistor T9 and the one end of the tenth MOS transistor T10 are connected to a terminal BUS. Output of the sensing amplifier circuit SA is provided to the terminal BUS.

The above is one example, and the sensing amplifier circuit SA is optionally configured.

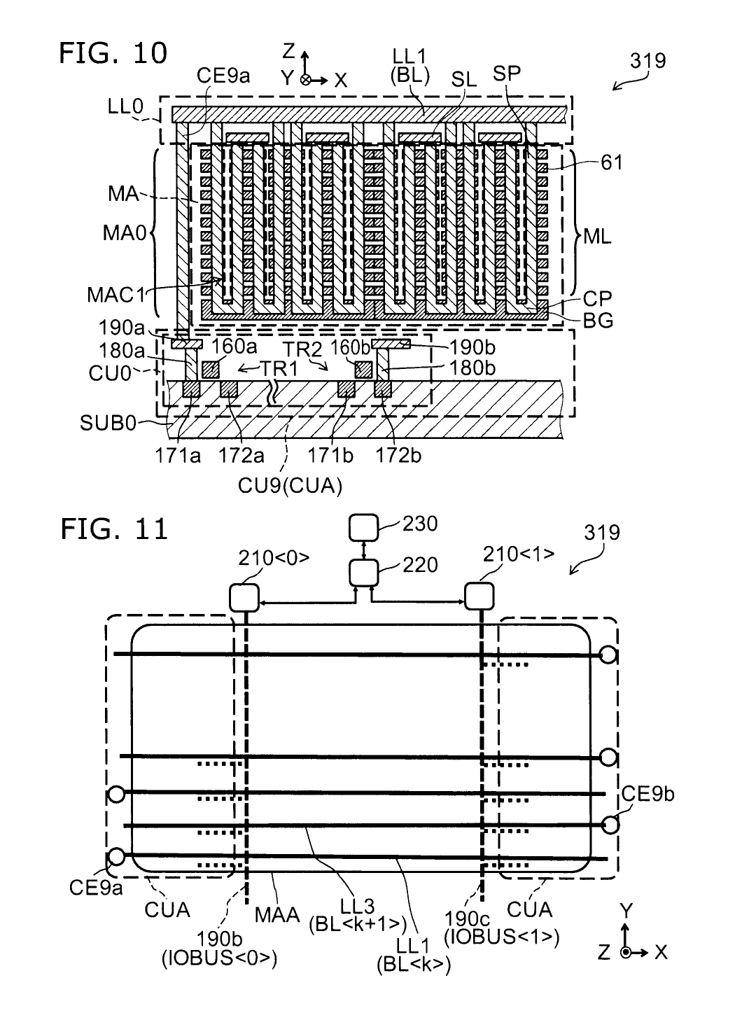

FIG. 10 is a schematic sectional view illustrating the configuration of the semiconductor memory device of a reference example.

In FIG. 10, conductive portions are shown and insulating portions are omitted for easy viewing.

As shown in FIG. 10, also in the semiconductor memory device 319 of the reference example, the substrate SUB0, the circuit layer CU0, the memory layer MA0 and the interconnect layer LL0 are provided.

However, one contact interconnect (first contact interconnect CE9a) is provided for one interconnect (for example, first interconnect LL1). This first contact interconnect CE9a is provided at an end of the first interconnect LL1 in the X-axis direction. The first contact interconnect CE9a is connected to the first array lower interconnect layer 190a of a circuit unit CU9. The second array lower interconnect layer 190b included in the circuit unit CU9 is used as the IOBUS connecting the circuit unit CU9 to the external circuit.

FIG. 11 is a block diagram illustrating the configuration of the semiconductor memory device of the reference example.

As shown in FIG. 11, the first interconnect LL1 (for example, bit line BL<k>) extends along the X-axis direction. The third interconnect LL3 (for example, bit line BL<k+1>) extends along the X-axis direction. The memory cell array unit MAA is provided below the first interconnect LL1 and the third interconnect LL3.

The first contact interconnect CE9a is provided at one end of the first interconnect LL1 in the X-axis direction. A second contact interconnect CE9b is provided at another end of the third interconnect LL3 in the X-axis direction. The first contact interconnect CE9a and the second contact interconnect CE9b are connected to the circuit unit CUA below the memory cell array unit MAA. Each of another ends of the circuit unit CUA is, for example, connected to the second array lower interconnect layer 190b and the third array lower interconnect layer 190c. The second array lower interconnect layer 190b is used as the IOBUS<0>, and the third array lower interconnect layer 190c is used as the IOBUS<1>.

The bit lines BL are provided usually with a minimum pitch. Therefore, in the reference example, the pitch of the contact interconnects (for example, first contact interconnect CE9a and second contact interconnect CE9b) is set to this minimum pitch or twice this minimum pitch. It is difficult to make the interconnects from the circuit unit CUA to the external circuit pass between the bit lines BL. Therefore, in the reference example, the interconnects from the circuit unit CUA to the external circuit are based on the lower side conductive layers (for example, second array lower interconnect layer 190b and the third array lower interconnect layer 190c) rather than the memory layer MA0.

In the semiconductor memory device 319 of the reference example having this configuration, the conductive layer included in the circuit layer CU0 below the memory layer MA0 is used as the IOBUS. Thus, the conductivity of the IOBUS is low. Therefore, the high-speed operation is difficult.

On the contrary, in the semiconductor memory device 310 according to the embodiment, the conductive layer (for example, second interconnect LL2 and fourth interconnect LL4) of the interconnect layer LL0 above the memory layer MA0 is used as the IOBUS. This can provide a semiconductor memory device operable at a high speed.

### Second Embodiment

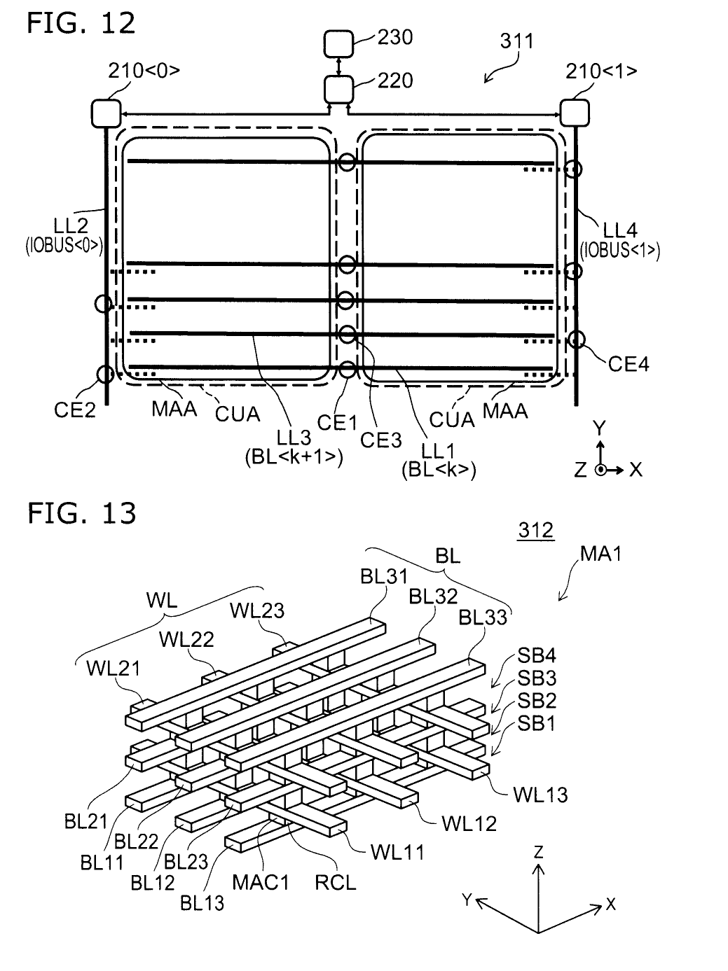

FIG. 12 is a block diagram illustrating the configuration of a semiconductor memory device according to a second embodiment.

The semiconductor memory device 311 according to the embodiment includes also the substrate SUB0, the interconnect layer LL0, the memory layer MA0, the circuit layer CU0, the first contact layer CE1 and the second contact layer CE2. The semiconductor memory device 311 includes the third contact interconnect CE3 and the fourth contact interconnect CE4. The configuration of the substrate SUB0, the interconnect layer LL0, the memory layer MA0 and the circuit layer CU0 is the same as that of the semiconductor memory device 310, and thus the description is omitted.

As shown in FIG. 12, in the semiconductor memory device 311, the first contact layer CE1 is provided almost at the center of the first interconnect LL1 in the X-axis direction. The third contact interconnect CE3 is provided almost at the center of the third interconnect LL3 in the X-axis direction.

In other words, a length of the first memory cell array unit MA1 along the X-axis direction is substantially the same as a length of the second memory cell array unit MA2 along the X-axis direction. The length of the first memory cell array unit MA1 along the X-axis direction is not less than 95% and not more than 105% of the length of the second memory cell array unit MA2 along the X-axis direction.

A length of the third memory cell array unit MA3 along the X-axis direction is substantially the same as a length of the fourth memory cell array unit MA4 along the X-axis direction. The length of the third memory cell array unit MA3 along the X-axis direction is not less than 95% and not more than 105% of the length of the fourth memory cell array unit MA4 along the X-axis direction.

Thus, the first contact interconnect CE1 is provided almost at the center of the first interconnect LL1 and the third contact interconnect CE3 is provided almost at the center of the third interconnect LL3, and thereby the chip area can be reduced.

In other words, in the semiconductor memory devices 320 and 311 according to the embodiment, since the contact interconnect is provided in the region of the memory cell array unit MAA, periodicity of the array is deteriorated. That is, a dummy cell region having the deteriorated periodicity of the array is provided.

In the semiconductor memory device 310 according to the first embodiment, since the first contact interconnect CE1 is not located almost at the center of the first interconnect LL1, and the third contact interconnect CE3 is not located almost at the center of the third interconnect LL3, six dummy cell regions are formed.

On the contrary, in the semiconductor memory device 311 according to the second embodiment, the first contact interconnect CE1 is provided almost at the center of the first interconnect LL1, and the third contact interconnect CE3 is provided almost at the center of the third interconnect LL3, and thereby the number of the dummy cell regions can be reduced to four. Thus, the chip area can be more desirably reduced.

Also in the semiconductor memory device 311, the conductive layer of the interconnect layer LL0 above the memory layer MA0 is used as the IOBUS. This can provide a semiconductor memory device operable at a high speed.

### Third Embodiment

FIG. 13 is a schematic perspective view illustrating the configuration of a semiconductor memory device according to a third embodiment.

In other words, FIG. 13 illustrates the configuration of a part of the memory cell array units MAA (for example, first to fourth memory cell array units MA1 to MA4).

As shown in FIG. 13, in the semiconductor memory device 312 according to the embodiment, for example, the bit lines BL extending along the X-axis direction and the word lines WL extending along the Y-axis direction are provided.

A resistance change layer RCL is provided between the bit line and the word line. In the resistance change layer, the resistance changes with at least one of the applied voltage and the passed current.

In other words, the semiconductor memory device 312 is a cross-point type resistance change memory.

For example, bit lines BL11, BL12 and BL13, and word lines WL11, WL12 and WL13 are provided as a first layer SB1. The resistance change layer RCL is provided between these lines.

Word lines WL11, WL12 and WL13, and bit lines BL21, BL22 and BL23 are provided as a second layer SB2. The resistance change layer RCL is provided between these lines.

Bit lines BL21, BL22 and BL23, and word lines WL21, WL22 and WL23 are provided as a third layer SB3. The resistance change layer RCL is provided between these lines.

Word lines WL21, WL22 and WL23, and bit lines BL31, BL32 and BL33 are provided as a fourth layer SB4. The resistance change layer RCL is provided between these lines.

Thus, the bit lines BL or the word lines WL are shared in an adjacent layer along the Z-axis direction.

In the semiconductor memory device 312, the plurality of memory cells included in the first memory cell array unit MA1 and the plurality of memory cells included in the second memory cell array unit MA2 include the resistance change layer RCL changing the resistance with at least one of the applied voltage and the passed current. The memory cells are stacked along the Z-axis direction.

In the semiconductor memory device 312 according to the embodiment, the first interconnect LL1 is, for example, connected to the bit line BL11. The third interconnect LL3 is connected to the bit line BL12.

The first interconnect LL1 is connected to the first circuit unit CU1 by the first contact interconnect CE1. The third interconnect LL3 is connected to the second circuit unit CU2 by the third contact interconnect CE3. The first circuit unit CU1 is connected to the second interconnect LL2 of the interconnect layer LL0 by the second contact interconnect CE2. The second circuit unit CU2 is connected to the fourth interconnect LL4 of the interconnect layer LL0 by the fourth contact interconnect CE4.

Also in the semiconductor memory device 312, the conductive layer of the interconnect layer LL0 above the memory layer MA0 is used as the IOBUS. This can provide a semiconductor memory device operable at a high speed.

Thus, in the semiconductor memory devices according to the embodiments, the memory cells are provided corresponding to portions where the word lines WL intersect the bit lines BL. The memory cell array unit MAA including the memory cells is provided above the substrate SUB0. The bit lines BL are provided above the memory cell array unit MAA. The circuit unit CUA including the sensing amplifier circuit SA reading/programming the data of the memory cells is provided below the memory cell array unit MAA.

The bit line BL (first interconnect LL1) is connected to the first circuit unit CU1 by the first contact interconnect CE1 extending along the Z-axis direction. Another end of the first circuit unit CU1 is connected to the second interconnect LL2 by the second contact interconnect CE2 extending along the Z-axis direction. The second interconnect LL2 is connected to the external circuit. The conductive layer of the upper interconnect layer LL0 is used as the interconnect connecting the sensing amplifier circuit to the external circuit. In other words, the conductive layer of the circuit layer CU0 with a high resistance is not used. This can provide a semiconductor memory device operable at a high speed.

In the specification of the application, “perpendicular” and “parallel” refer to not only strictly perpendicular and strictly parallel but also include, for example, the fluctuation due to manufacturing processes, etc. It is sufficient to be substantially perpendicular and substantially parallel.

Hereinabove, exemplary embodiments of the invention are described with reference to specific examples. However, the embodiments of the invention are not limited to these specific examples. For example, one skilled in the art may similarly practice the invention by appropriately selecting specific configurations of components included in semiconductor memory devices such as a substrate, interconnect layers, memory layers, circuit layers, circuit units, memory cell array units, memory cells, interconnects, contact interconnects, etc., from known art. Such practice is included in the scope of the invention to the extent that similar effects thereto are obtained.

Further, any two or more components of the specific examples may be combined within the extent of technical feasibility and are included in the scope of the invention to the extent that the purport of the invention is included.

Moreover, all semiconductor memory devices practicable by an appropriate design modification by one skilled in the art based on the semiconductor memory devices described above as embodiments of the invention also are within the scope of the invention to the extent that the purport of the invention is included.

Various other variations and modifications can be conceived by those skilled in the art within the spirit of the invention, and it is understood that such variations and modifications are also encompassed within the scope of the invention.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A nonvolatile memory device comprising:
a substrate having a major surface;
an interconnect layer provided on the major surface, the interconnect layer including:
a first interconnect extending along a first direction parallel to the major surface; and
a second interconnect;
a memory layer provided between the substrate and the interconnect layer, the memory layer including:
a first memory cell array unit including a plurality of memory cells electrically connected to the first interconnect; and
a second memory cell array unit juxtaposed to the first memory cell array unit along the first direction and including a plurality of memory cells electrically connected to the first interconnect;
a circuit layer provided between the memory layer and the substrate and including a first circuit unit;
a first contact interconnect extending along a second direction from the substrate toward the interconnect layer between the first memory cell array unit and the second memory cell array unit and electrically connecting one end of the first circuit unit to the first interconnect; and
a second contact interconnect extending along the second direction on a opposite side of the first memory cell array unit to the first contact interconnect and electrically connecting a second end of the first circuit unit different from the first end to the second interconnect.

2. The device according to claim 1, wherein the first circuit unit includes a sensing amplifier circuit configured to detect electrical characteristics of the plurality of memory cells included in the first memory cell array unit and the plurality of memory cells included in the second memory cell array unit.

3. The device according to claim 2, wherein the first circuit unit includes a latch, which is connected to the sensing amplifier circuit.

4. The device according to claim 2, further comprising:
a pad unit,
the second interconnect electrically connecting the sensing amplifier circuit to the pad unit.

5. The device according to claim 4, wherein
the second interconnect is configured to input data to the sensing amplifier circuit, the input data being inputted from the pad unit.

6. The device according to claim 1, wherein
the second interconnect has a portion extending along a third direction perpendicular to the first direction and the second direction.

7. The device according to claim 1, wherein
at least a part of the first circuit unit is disposed between the first memory cell array unit and the substrate.

8. The device according to claim 1, wherein
a length of the first memory cell array unit along the first direction is shorter than a length of the second memory cell array unit along the first direction.

9. The device according to claim 1, wherein
electrical conductivity of a metal material included in the circuit layer is lower than electrical conductivity of a metal material included in the interconnect layer.

10. The device according to claim 1, wherein
a thermal stability of a metal material included in the circuit layer is higher than a thermal stability of a metal material included in the interconnect layer.

11. The device according to claim 1, further comprising:
a third contact interconnect; and
a fourth contact interconnect,
the interconnect layer further includes
a third interconnect extending along the first direction and
a fourth interconnect,
the memory layer further includes
a third memory cell array unit having at least a part juxtaposed to the first memory cell array unit along a third direction perpendicular to the first direction and the second direction, and including a plurality of memory cells electrically connected to the third interconnect, and
a fourth memory cell array unit having at least a part juxtaposed the third memory cell array along the first direction, juxtaposed to the second memory cell array unit along the third direction, and including a plurality of memory cells electrically connected to the third interconnect,
the circuit layer further includes a second circuit unit,
the third contact interconnect extends along the second direction between the third memory cell array unit and the fourth memory cell array unit, and electrically connecting a third end of the second circuit unit to the third interconnect,
the fourth contact interconnect extends along the second direction on an opposite side of the fourth memory cell array unit to the third contact interconnect, and electrically connecting a fourth end of the second circuit unit different from the third end to the fourth interconnect, and
a position of the first contact interconnect along the first direction and a position of the third contact interconnect along the first direction are disposed between a position of the second contact interconnect along the first direction and a position of the fourth contact interconnect along the first direction.

12. The device according to claim 11, wherein the first circuit unit includes a sensing amplifier circuit configured to detect electrical characteristics of the plurality of memory cells included in the third memory cell array unit and the plurality of memory cells included in the fourth memory cell array unit.

13. The device according to claim 11, further comprising:
a pad unit,
the fourth interconnect electrically connects the sensing amplifier circuit to the pad unit.

14. The device according to claim 11, wherein
the fourth interconnect has a portion extending along a third direction perpendicular to the first direction and the second direction.

15. The device according to claim 1, further comprising:
a third contact interconnect; and
a fourth contact interconnect,
the interconnect layer further includes
a third interconnect extending along the first direction and
a fourth interconnect,
the memory layer further includes
a third memory cell array unit having at least a part juxtaposed to the first memory cell array unit along a third direction perpendicular to the first direction and the second direction, and including a plurality of memory cells electrically connected to the third interconnect, and
a fourth memory cell array unit having at least a part juxtaposed the third memory cell array along the first direction, juxtaposed to the second memory cell array unit along the third direction, and including a plurality of memory cells electrically connected to the third interconnect,
the circuit layer further includes a second circuit unit,
the third contact interconnect extends along the second direction between the third memory cell array unit and the fourth memory cell array unit, and electrically connecting a third end of the second circuit unit to the third interconnect,
the fourth contact interconnect extends along the second direction on an opposite side of the fourth memory cell array unit to the third contact interconnect, and electrically connecting a fourth end of the second circuit unit different from the third end to the fourth interconnect,
a length of the first memory cell array unit along the first direction is equal to a length of the second memory cell array unit along the first direction, and
a length of the third memory cell array unit along the first direction is equal to a length of the fourth memory cell array unit along the first direction.

16. The device according to claim 15, wherein the first circuit unit includes a sensing amplifier circuit configured to detect electrical characteristics of the plurality of memory cells included in the third memory cell array unit and the plurality of memory cells included in the fourth memory cell array unit.

17. The device according to claim 15, further comprising:
a pad unit,
the fourth interconnect electrically connects the sensing amplifier circuit to the pad unit.

18. The device according to claim 15, wherein
the fourth interconnect has a portion extending along a third direction perpendicular to the first direction and the second direction.

19. The device according to claim 1, wherein
the first memory cell array unit includes
a stacked structure including a plurality of electrode films stacked along the second direction and an inter-electrode insulating film provided between the plurality of electrode films,
a semiconductor layer facing side surfaces of the plurality of electrode films along the second direction,
a memory layer provided between the semiconductor layer and the plurality of electrode films,
a first insulating film provided between the memory layer and the semiconductor layer, and
a second insulating film provided between the memory layer and the plurality of electrode films,
the semiconductor layer is electrically connected to the first interconnect, and
each of the plurality of memory cells included in the first memory cell array unit is provided in a portion where each of the plurality of electrode films faces the semiconductor layer.

20. The device according to claim 1, wherein
the first memory cell array unit includes
a first stacked structure including a plurality of first electrode films stacked along the second direction and a first inter-electrode insulating film provided between the plurality of first electrode films,
a first semiconductor pillar piercing the first stacked structure along the second direction,
a first memory layer provided between the first semiconductor pillar and the plurality of first electrode films,
a first inner insulating film provided between the first memory layer and the first semiconductor pillar, and
a first outer insulating film provided between the first memory layer and the plurality of electrode films,
the first semiconductor pillar is electrically connected to the first interconnect, and
each of the plurality of memory cells included in the first memory cell array unit is provided in a portion where each of the plurality of first electrode films intersect the first semiconductor pillar.
